(19) United States
(12) Patent Application Publication
(10) Pub. No.: US 2025/0176189 A1
(43) Pub. Date: May 29, 2025

(54) SEMICONDUCTOR MEMORY DEVICE

(71) Applicant: SAMSUNG ELECTRONICS CO., LTD., Suwon-si (KR)

(72) Inventors: Minsu Kim, Suwon-si (KR); Hongsoo Jeon, Suwon-si (KR)

(21) Appl. No.: 18/742,550

(22) Filed: Jun. 13, 2024

(30) Foreign Application Priority Data
Nov. 23, 2023 (KR) 10-2023-0163907

(51) Int. Cl. H10B 43/40; G11C 16/24; H10B 41/27; H10B 41/41; H10B 43/27

(52) U.S. Cl. CPC H10B 43/40; G11C 16/24; H10B 41/27; H10B 41/41; H10B 43/27

(57) ABSTRACT

A semiconductor memory device includes a memory cell array that is formed in a memory cell region, and a page buffer circuit that is formed in a peripheral circuit region and includes a plurality of page buffer units each including a sensing node for reading data stored in the memory cell array. The sensing node includes a lower metal pattern that extends in a first horizontal direction and one or more upper metal patterns that are spaced from the lower metal pattern in a vertical direction, electrically connected to the lower metal pattern and extend in a second horizontal direction being perpendicular to the first horizontal direction or in a direction facing away from the second horizontal direction.

### CROSS-REFERENCE TO RELATED APPLICATION

This application claims priority to and the benefit of Korean Patent Application No. 10-2023-0163907 filed in the Korean Intellectual Property Office on Nov. 23, 2023, the disclosure of which is incorporated by reference herein in its entirety.

### BACKGROUND

A semiconductor memory device may be classified as a volatile memory device or a nonvolatile memory device. The volatile memory device may retain data stored therein while a power is supplied, and the nonvolatile memory device may retain data stored therein even though a power is turned off. The volatile memory device provides a fast speed, and the nonvolatile memory device provides excellent safety and endurance. The semiconductor memory device may include a page buffer circuit to efficiently exchange data with an external host device. The page buffer circuit may include sensing nodes. Based on changes in voltage levels of the sensing nodes, the page buffer circuit may read data stored in a memory cell array or may write data in the memory cell array.

For the reliability of the read or write operation, each sensing node should have a capacitance of a given value or more. However, as the degree of integration of the semiconductor memory device is improved, in the semiconductor memory device, the area where a page buffer is capable of being implemented may decrease, and the size (or length) of each sensing node may also decrease. As the size of each sensing node decreases, a value of the capacitance of each sensing node may also decrease. Accordingly, a way to implement sensing nodes with sufficient capacitances is required.

### SUMMARY

In general, in some aspects, the present disclosure is directed toward a semiconductor memory device having a sensing node of a page buffer with particular capacitance.

According to some implementations, the present disclosure is directed to a semiconductor memory device having a memory cell array that is formed in a memory cell region, and a page buffer circuit that is formed in a peripheral circuit region and includes a plurality of page buffer units each including a sensing node for reading data stored in the memory cell array. The sensing node includes a lower metal pattern that extends in a first horizontal direction and one or more upper metal patterns that are spaced from the lower metal pattern in a vertical direction, electrically connected to the lower metal pattern and extend in a second horizontal direction being perpendicular to the first horizontal direction or in a direction facing away from the second horizontal direction.

According to some aspects, the present disclosure is directed to a semiconductor memory device having a memory cell array formed in a memory cell region, and a page buffer circuit formed in a peripheral circuit region and including a plurality of page buffer units including a first page buffer unit and a second page buffer unit. A first sensing node of the first page buffer unit includes a first lower metal pattern that extends in a first horizontal direction, and one or more first upper metal patterns that are spaced from the first lower metal pattern in a vertical direction and extending in a second horizontal direction being perpendicular to the first horizontal direction or in a direction facing away from the second horizontal direction, and a second sensing node of the second page buffer unit includes a second lower metal pattern that extends in the first horizontal direction and one or more second upper metal patterns that are spaced from the second lower metal pattern in the vertical direction and extending in the second horizontal direction or in the direction facing away from the second horizontal direction.

According to some aspects, the present disclosure is directed to a semiconductor memory device having a cell over periphery (or cell on periphery) (COP) that includes a memory cell array formed in a memory cell region, and a page buffer circuit formed in a peripheral circuit region disposed under the memory cell region and including a plurality of page buffer units each including a sensing node for reading data stored in the memory cell array. The sensing node includes a lower metal pattern that extends in a first horizontal direction and one or more upper metal patterns that are spaced from the lower metal pattern in a vertical direction, are electrically connected to the lower metal pattern, and extend in a second horizontal direction being perpendicular to the first horizontal direction or in a direction facing away from the second horizontal direction. The peripheral circuit region includes a lower metal layer, and an upper metal layer disposed over the lower metal layer. The lower metal pattern is formed in the lower metal layer, and the one or more upper metal patterns are formed in the upper metal layer.

### BRIEF DESCRIPTION OF THE DRAWINGS

Example implementations will be more clearly understood from the following detailed description, taken in conjunction with the accompanying drawings.

FIG. 1 is a diagram illustrating an example of a semiconductor memory device according to some implementations.

FIG. 2 is a block diagram for describing an example of a semiconductor memory device of FIG. 1 according to some implementations.

FIG. 3 is a diagram for describing examples of memory blocks included in a memory cell array of FIG. 2 according to some implementations.

FIG. 4 is a perspective view illustrating an example of the memory blocks of FIG. 3 according to some implementations.

FIG. 5 is a block diagram illustrating an example of a page buffer circuit of FIGS. 1 and 2 according to some implementations.

FIG. 6 is a block diagram illustrating an example of a page buffer unit of FIG. 5 according to some implementations.

FIG. 7 is a cross-sectional view illustrating an example of the semiconductor memory device of FIG. 1 according to some implementations.

FIGS. 8, 9, 10, 11, and 12 are diagrams illustrating examples of a sensing node included in a page buffer unit of FIG. 1 according to some implementations.

FIG. 13 is a diagram for describing examples of shielding patterns included in the semiconductor memory device of FIG. 1, 2, or 5, and capable of being implemented together with sensing nodes illustrated in FIGS. 8 to 12 according to some implementations.

FIG. 14 is a diagram illustrating an example of an electronic system including a semiconductor memory device according to some implementations.

### DETAILED DESCRIPTION

Hereinafter, example implementations will be explained in detail with reference to the accompanying drawings.

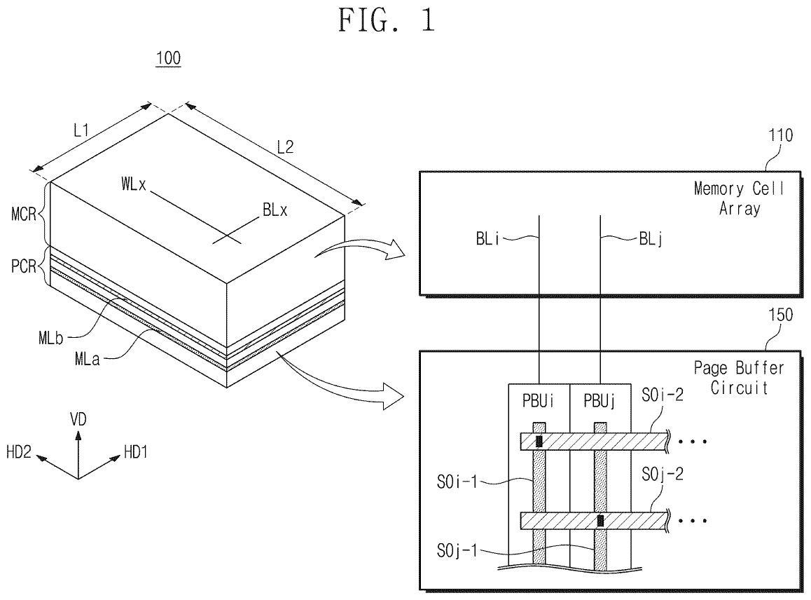

FIG. 1 is a diagram illustrating an example of semiconductor memory device according to some implementations. In FIG. 1, a vertical direction VD, a first horizontal direction HD1, and a second horizontal direction HD2 are perpendicular to each other. In the accompanying drawings, the vertical direction VD, the first horizontal direction HD1, and the second horizontal direction HD2 may be used in common. The first horizontal direction HD1 may be identical to a bit line extension direction in which bit lines horizontally extend in a memory cell region of a semiconductor memory device, but the present disclosure is not limited thereto.

In FIG. 1, a semiconductor memory device 100 may include a memory cell array 110 and a page buffer circuit 150. The memory cell array 110 may include a plurality of memory cells which are formed at intersections of a plurality of word lines (e.g., WLx) and a plurality of bit lines (e.g., BLx). The plurality of memory cells may store data provided to the semiconductor memory device 100 under control of an external memory controller or an internal control circuit of the semiconductor memory device 100.

The page buffer circuit 150 may include a plurality of page buffer units (e.g., PBUi and PBUj). Each of the plurality of page buffer units may include a sensing node. Based on a change in the voltage level of the sensing node (or the amount of charges stored by the capacitance of the sensing node), each of the plurality of page buffer units may read data stored in the memory cell array 110 or may write data in the memory cell array 110.

In some implementations, each of the plurality of page buffer units may be a unit component of the page buffer circuit 150, which is used to read or write data associated with memory cells connected to a specific bit line from among the plurality of memory cells. For example, the page buffer unit PBUi may be connected to a bit line BLi, and the page buffer unit PBUj may be connected to a bit line BLj. The page buffer unit PBUi may be used to read or write data from or in memory cells connected to the bit line BLi, and the page buffer unit PBUj may be used to read or write data from or in memory cells connected to the bit line BLj.

The sensing node should have a capacitance of a given value or more for the purpose of the reliability of the read or write operation. However, as the degree of integration of the semiconductor memory device 100 is improved, the area (e.g., L1×L2) where the page buffer circuit 150 is capable of being implemented may decrease, and the size (or length) of the sensing node may also decrease. This may mean that the capacitance of the sensing node is not sufficient. Accordingly, in the semiconductor memory device 100 according to an embodiment of the present disclosure, the sensing node may be implemented by metal patterns with given shapes such that the sensing node has a capacitance of a sufficient value within the area where the page buffer circuit 150 (or a page buffer unit) is capable of being implemented

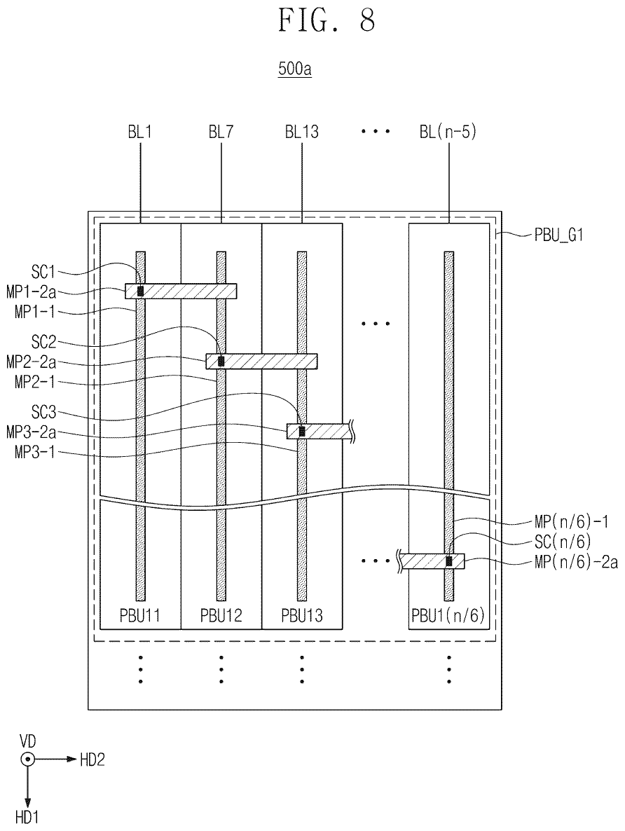

In some implementations, the sensing node may include a lower metal pattern and one or more upper metal patterns, which extend in given directions, respectively. For example, the lower metal pattern may extend in a first horizontal direction (e.g., HD1). The one or more upper metal patterns may be spaced from the lower metal pattern in a vertical direction (e.g., VD), may be electrically connected to the lower metal pattern, and may extend in a second horizontal direction (e.g., HD2) or a direction facing away from the second horizontal direction. For example, the sensing node of the page buffer unit PBUi (or the sensing node included in the page buffer unit PBUi) may include a lower metal pattern SOi-1 and an upper metal pattern SOi-2, and the sensing node of the page buffer unit PBUj (or the sensing node included in the page buffer unit PBUj) may include a lower metal pattern SOj-1 and an upper metal pattern SOj-2. The lower metal patterns SOi-1 and SOj-1 may extend in the first horizontal direction, the upper metal pattern SOi-2 may extend in the second horizontal direction, and the upper metal pattern SOj-2 may extend in the second horizontal direction or the direction facing away from the second horizontal direction. However, the present disclosure is not limited thereto. The sensing node will be described with reference to FIGS. 8 to 12.

The semiconductor memory device 100 may include a memory cell region MCR and a peripheral circuit region PCR for implementing the memory cell array 110 and the page buffer circuit 150.

In some implementations, the semiconductor memory device 100 may have a cell over periphery (cell on periphery) (COP) structure, such as illustrated in FIG. 1, the memory cell region MCR may be disposed on the peripheral circuit region PCR (or on the upper surface of the peripheral circuit region PCR). However, the present disclosure is not limited thereto. In some implementations, the peripheral circuit region PCR may be disposed on the memory cell region MCR (or on the upper surface of the memory cell region MCR). In some implementations, a first portion and a second portion of the peripheral circuit region PCR may be distributed and disposed on the upper surface and the lower surface of the memory cell region MCR.

In some implementations, the peripheral circuit region PCR may include metal layers MLa and MLb. The metal layer MLb may be an “upper metal layer” disposed on/over the metal layer MLa, and the metal layer MLa may be a “lower metal layer” disposed under the metal layer MLb. In this case, the lower metal pattern may be formed in the lower metal layer, and the one or more upper metal patterns may be formed in the upper metal layer. For example, the lower metal patterns SOi-1 and SOj-1 may be formed in the metal layer MLa, and the upper metal patterns SOi-2 and SOj-2 may be formed in the metal layer MLb.

In some implementations, the sensing node may only include the lower metal pattern and the one or more upper metal patterns. For example, the sensing node may be implemented only with the lower metal pattern and the one or more upper metal layers and may not include any other metal patterns other than the lower metal pattern and the one or more upper metal layers.

In some implementations, when viewed in the vertical direction VD (or in a plan view of the semiconductor memory device 100), each of the one or more upper metal patterns may form an angle of 90 degrees with the lower metal pattern.

In the above configuration, a semiconductor memory device may include a page buffer circuit including a plurality of page buffer units, each of the plurality of page buffer units may include a sensing node, and the sensing node may be implemented by metal patterns with given shapes. The metal patterns may include a lower metal pattern and one or more upper metal patterns respectively extending in given directions, and the capacitance of the sensing node may have a given value determined by the lower metal pattern and may be increased by the one or more upper metal patterns. The sensing node may be implemented by the above metal patterns to have a capacitance of a sufficient value and may satisfy the hardware specifications associated with read or write performance of a semiconductor memory device even in an external environment including a noise or the like.

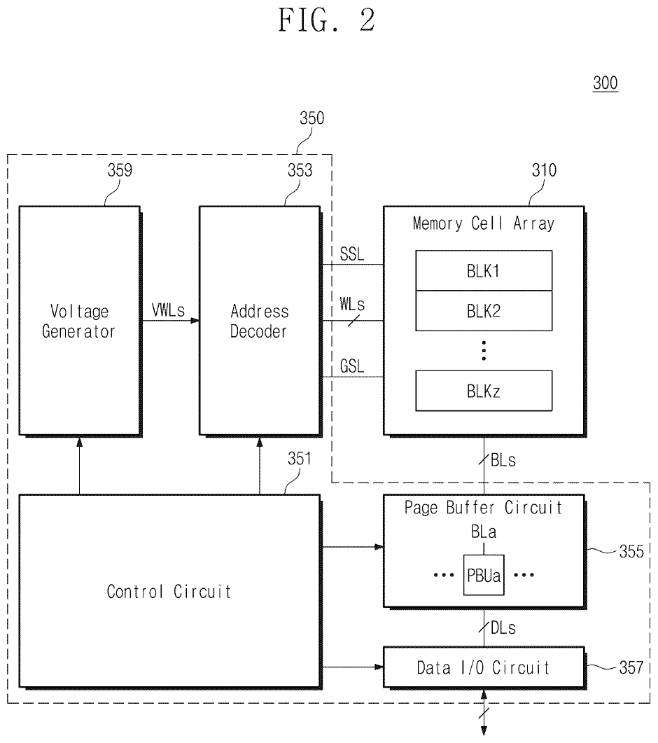

FIG. 2 is a block diagram for describing an example of a semiconductor memory device of FIG. 1 according to some implementations. In FIG. 2, a semiconductor memory device 300 may be a nonvolatile memory device and may include a memory cell array 310 and peripheral circuit 350.

The memory cell array 310 may include a plurality of memory blocks BLK1, BLK2, . . . , BLKz, and the peripheral circuit 350 may include a control circuit 351, an address decoder 353, a page buffer circuit 355, a data input/output circuit 357, and a voltage generator 359. Additionally, the peripheral circuit 350 may further include an input/output interface, a pre-decoder, a temperature sensor, etc.

The memory cell array 310 may be connected to the address decoder 353 through a string selection line SSL, a plurality of word lines WLs, and a ground selection line GSL. The memory cell array 310 may be connected to the page buffer circuit 355 through a plurality of bit lines BLs. The memory cell array 310 may include a plurality of memory cells connected to the plurality of word lines WLs and the plurality of bit lines BLs.

In some implementations, the memory cell array 310 may be a three-dimensional (3D) memory cell array formed on a substrate in a 3D (or vertical) structure. Accordingly, the memory cell array 310 may include vertical memory cell strings including the plurality of memory cells.

The control circuit 351 may receive a control signal, a command signal, and an address signal from an external memory controller and may control the write operation, the read operation, and the erase operation of the semiconductor memory device 300 based on the control signal, the command signal, and the address signal.

For example, the control circuit 351 may generate control signals for controlling the voltage generator 359 and control signals for controlling the page buffer circuit 355 based on the command signal and may generate a row address and a column address based on the address signal. The control circuit 351 may control the write operation, the read operation, and the erase operation of the semiconductor memory device 300 by providing the row address to the address decoder 353 and providing the column address to the data input/output circuit 357.

The address decoder 353 may be connected to the memory cell array 310 through the string selection line SSL, the plurality of word lines WLs, and the ground selection line GSL. In the write operation or the read operation, the address decoder 353 may determine one of the plurality of word lines WLs as a selected word line based on the row address from the control circuit 351 and may determine the remaining word lines among the plurality of word lines WLs other than the selected word line as unselected word lines.

The voltage generator 359 may generate word line voltages VWLs necessary for the operation of the semiconductor memory device 300 based on the control signals from the control circuit 351. The word line voltages VWLs generated by the voltage generator 359 may be applied to the plurality of word lines WLs through the address decoder 353.

For example, in the erase operation, the voltage generator 359 may generate an erase voltage to be applied to wells of the memory blocks BLK1 to BLKz; in this case, the ground voltage may be applied to all the word lines WLs of the memory blocks BLK1 to BLKz. In the erase verify operation, the voltage generator 359 may generate an erase verify voltage to be applied to all word lines of one memory block or to be applied in units of word line.

For example, in the write operation, the voltage generator 359 may generate a program voltage to be applied to the selected word line and may generate a program pass voltage to be applied to the unselected word lines. In the program verify operation, the voltage generator 359 may generate a program verify voltage to be applied to the selected word line and may generate a verify pass voltage to be applied to the unselected word lines.

For example, in the read operation, the voltage generator 359 may generate a read voltage to be applied to the selected word line and may generate a read pass voltage to be applied to the unselected word lines.

The page buffer circuit 355 may be connected to the memory cell array 310 through the plurality of bit lines BLs. The page buffer circuit 355 may include a plurality of page buffer units. The page buffer circuit 355 may temporarily store data to be written at a selected page in the program operation and data read from the selected page in the read operation. The page buffer unit (e.g., PBUa) may be a unit component of the page buffer circuit 355, which is used to read or write data from or in memory cells connected to a specific bit line (e.g., BLa).

The data input/output circuit 357 may be connected to the page buffer circuit 355 through a plurality of data lines DLs. In the program operation, the data input/output circuit 357 may receive data from the memory controller and may provide the data to the page buffer circuit 355 based on the column address from the control circuit 351. In the read operation, the data input/output circuit 357 may provide the data stored in the page buffer circuit 355 to the memory controller based the column address from the control circuit 351. The data lines DLs may be referred to as “data input/output lines”, and the data input/output circuit 357 may include input/output pads connected to the data input/output lines.

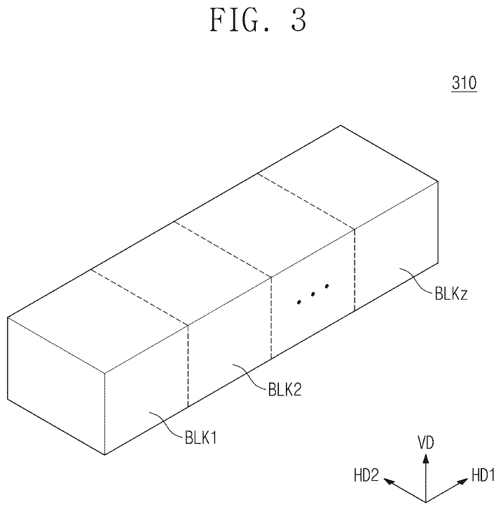

FIG. 3 is a diagram for describing examples of memory blocks included of a memory cell array of FIG. 2 according to some implementations. In FIGS. 2 and 3, the memory cell array 310 may include the plurality of memory blocks BLK1 to BLKz, and each of the plurality of memory blocks BLK1 to BLKz may have the 3D structure (or vertical structure).

In some implementations, each of the plurality of memory blocks BLK1 to BLKz may include a plurality of NAND strings extending in the vertical direction VD. In this case, the plurality of NAND strings may be spaced from each other along the first horizontal direction HD1 and the second horizontal direction HD2 as much as a specific distance. The memory blocks BLK1 to BLKz may be selected by an address decoder (e.g., 353 of FIG. 2). For example, the address decoder may select a memory block corresponding to a block address from among the plurality of memory blocks BLK1 to BLKz.

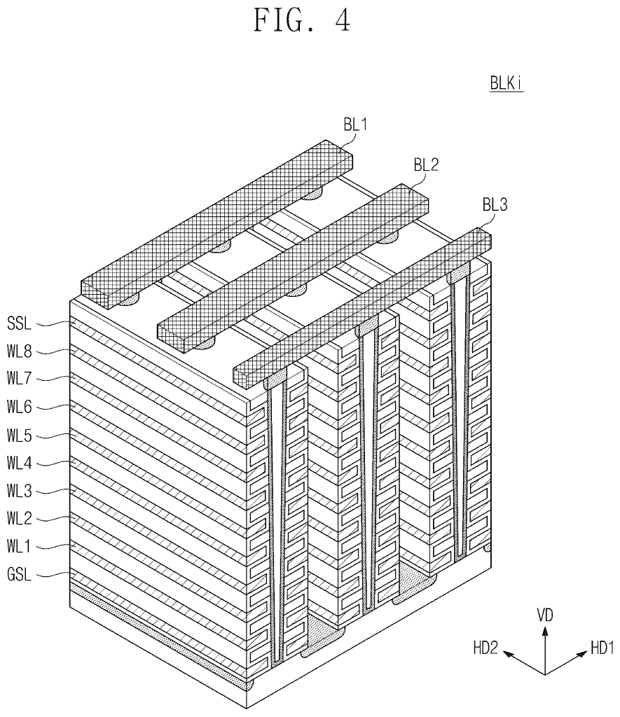

FIG. 4 is a perspective view illustrating an example of the memory blocks of FIG. 3 according to some implementations. In FIG. 4, the memory block BLKi may be one of the memory blocks BLK1 to BLKz described with reference to FIG. 3 and may be formed in the vertical direction VD perpendicular to the substrate. The substrate may be of a first conductivity type (e.g., a p-type), and a common source line which extends along the second horizontal direction HD2 and is doped with impurities of a second conductivity type (e.g., an n-type) may be provided on the substrate. On a region of the substrate between two adjacent common source lines, a plurality of insulating layers which extend along the second horizontal direction HD2 may be sequentially provided along the vertical direction VD, and the plurality of insulating layers may include an insulating material such as a silicon oxide.

A plurality of pillars which are sequentially disposed along the first horizontal direction HD1 and penetrate the plurality of insulating layers along the vertical direction VD may be provided on the region of the substrate between the two adjacent common source lines. For example, the plurality of pillars may penetrate the plurality of insulating layers and may be connected to the substrate.

The ground selection line GSL, word lines WL1, WL2, WL3, WL4, WL5, WL6, WL7, and WL8, and the string selection line SSL may be provided in the region of the two adjacent common source lines.

Drains or drain contacts may be respectively provided on the plurality of pillars. For example, the drains or the drain contacts may include an impurity-doped silicon material. Bit lines BL1, BL2, and BL3 which extend in the first horizontal direction HD1 and are spaced from each other along the second horizontal direction HD2 as much as a specific distance may be provided on the drains. The number of bit lines illustrated in FIG. 4 is provided as an example.

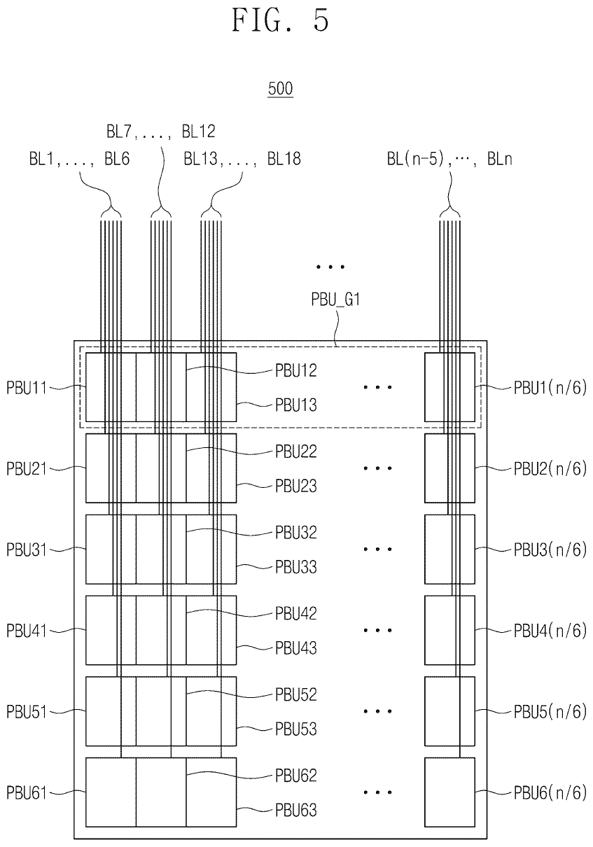

FIG. 5 is a block diagram illustrating an example of a page buffer circuit of FIGS. 1 and 2 according to some implementations. In FIG. 5, a page buffer circuit 500 may include a plurality of page buffer units PBU11, PBU12, PBU13, . . . , PBU1(n/6), PBU21, PBU22, PBU23, . . . , PBU2(n/6), PBU31, PBU32, PBU33, . . . , PBU3(n/6), PBU41, PBU42, PBU43, . . . , PBU4(n/6), PBU51, PBU52, PBU53, . . . , PBU5(n/6), PBU61, PBU62, PBU63, . . . , PBU6(n/6) respectively connected to a plurality of bit lines BL1, . . . , BL6, BL7, . . . , BL12, BL13, . . . , BL18, . . . , BL(n−5), . . . , BLn.

In some implementations, the page buffer circuit 500 may include page buffer units, the number of which is equal to the number of bit lines BL1 to BLn, and the page buffer units may be disposed at rows and columns. In some implementations, the plurality of page buffer units PBU11 to PBU1(n/6), PBU21 to PBU2(n/6), PBU31 to PBU3(n/6), PBU41 to PBU4(n/6), PBU51 to PBU5(n/6), and PBU61 to PBU6(n/6) are disposed at six rows is illustrated in FIG. 5, but the present disclosure is not limited thereto. Page buffer units may be disposed in the page buffer circuit 500 as the arrangement of rows and columns, which is implemented to have various sizes.

In some implementations, for convenience of description, in the page buffer circuit 500, page buffer units disposed at one row may be referred to as a “page buffer unit group”. For example, the page buffer units PBU11 to PBU1(n/6) may be referred to as a “page buffer unit group PBU_G1”. Below, shapes of metal patterns for implementing sensing nodes will be described based on the page buffer units PBU11 to PBU1(n/6) included in the page buffer unit group PBU_G1.

However, in the page buffer circuit 500, shapes of metal patterns for implementing sensing nodes included in the page buffer units PBU21 to PBU2(n/6), PBU31 to PBU3(n/6), PBU41 to PBU4(n/6), PBU51 to PBU5(n/6), and PBU61 to PBU6(n/6) disposed at rows different from that of the page buffer units PBU11 to PBU1(n/6) may be identical or similar to the shapes of the metal patterns for implementing the sensing nodes of the page buffer units PBU11 to PBU1(n/6).

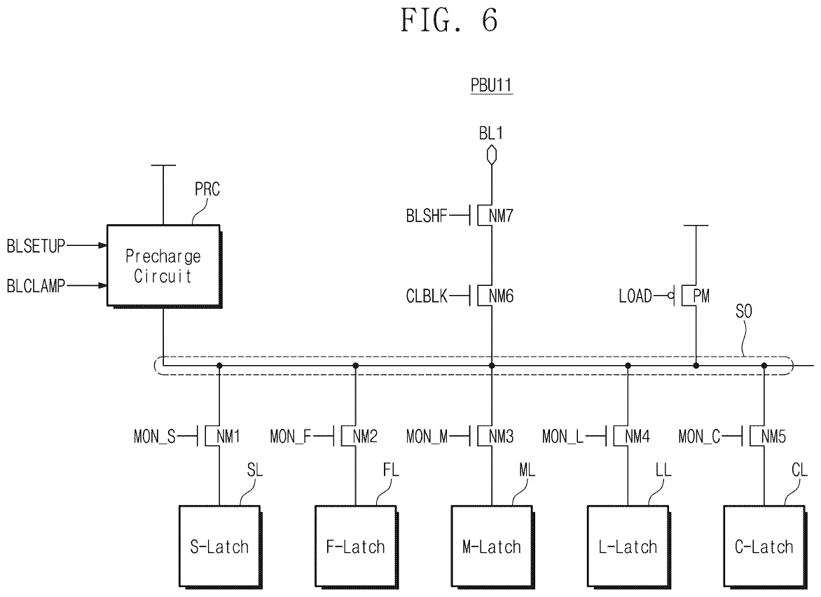

FIG. 6 is a block diagram illustrating an example of a page buffer unit of FIG. 5 according to some implementations. In FIG. 6, the page buffer unit PU11 may be connected to the bit line BL1 and may include a precharge circuit PRC, a sensing latch SL, a force latch FL, an upper bit latch ML, a lower bit latch LL, a cache latch CL, and a plurality of transistors NM1, NM2, NM3, NM4, NM5, NM6, NM7, and PM.

The precharge circuit PRC may control a precharge operation on the bit line BL1 or a sensing node SO based on a bit line setup control signal BLSETUP and a bit line clamping control signal BLCLAMP.

In the read operation of the semiconductor memory device, the sensing latch SL may store data to be written in the memory cell array or a result of sensing threshold voltages of the memory cells; in the program operation of the semiconductor memory device, the sensing latch SL may provide a write voltage or a write-inhibited voltage to the bit line BL1.

In the program operation, the force latch FL may contribute to the improvement of the distribution of threshold voltages of target memory cells, by determining whether the threshold voltages reach a target zone as values of data bits stored in the force latch FL are changed depending on the threshold voltages of the target memory cells.

The upper bit latch ML, the lower bit latch LL, and the cache latch CL may store data received from the outside (e.g., an external host device or a memory controller) in the program operation and may be collectively referred to as a “data latch”. When 3-bit data are stored in one memory cell, the three data bits may be respectively stored in the upper bit latch ML, the lower bit latch LL, and the cache latch CL; the data latch may maintain the data stored therein. In the read operation, the cache latch CL may be provided with data read from a memory cell from the sensing latch SL and may output the data to the outside through a data input/output line.

The transistors NM1, NM2, NM3, NM4, and NM5 may be respectively connected between the sensing node SO and the latches SL, FL, ML, LL, and CL. The transistors NM6 and NM7 may be connected in series between the sensing node SO and the bit line BL1. The transistor PM may be connected between a power supply voltage and the sensing node SO. The transistors NM1, NM2, NM3, NM4, NM5, NM6, NM7, and PM may be turned on or turned off based on control signals MON_S, MON_F, MON_M, MON_L, MON_C, CLBLK, BLSHF, and LOAD. The bit line setup control signal BLSETUP, the bit line clamping control signal BLCLAMP, and the control signals MON_S, MON_F, MON_M, MON_L, MON_C, CLBLK, BLSHF, and LOAD may be provided from a control circuit (e.g., 351 of FIG. 2) of the semiconductor memory device.

In the program operation or the read operation, the page buffer unit PU11 may read or program data from or in a memory cell connected to the bit line BL1 based on a change in the voltage level of the sensing node SO. For the reliability of the read or program operation, the sensing node SO should have a capacitance of a given value or more. The sensing node SO may include a lower metal pattern and one or more upper metal patterns (or may be implemented by using the lower metal pattern and the one or more upper metal patterns) and may form a metal-insulator-metal (MIM) capacitor with one or more adjacent metal patterns. The MIM capacitor may have a high frequency response, a small size, and a low noise characteristic.

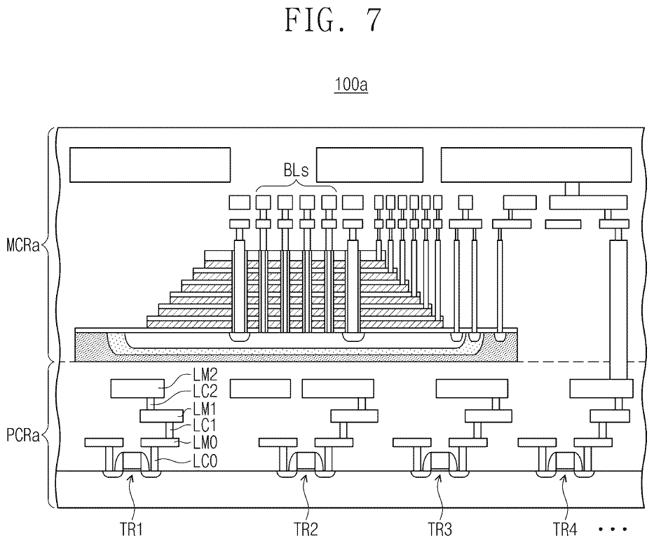

FIG. 7 is a cross-sectional view illustrating an example of the semiconductor memory device of FIG. 1 according to some implementations. In FIG. 7, a semiconductor memory device 100a may correspond to the semiconductor memory device 100 of FIG. 1. Accordingly, the semiconductor memory device 100a may include a memory cell region MCRa and a peripheral circuit region PCRa for implementing a memory cell array and a page buffer circuit.

In some implementations, the semiconductor memory device 100 may have a cell over periphery (cell on periphery) (COP) structure, and the memory cell region MCRa may be disposed on the peripheral circuit region PCRa. However, the present disclosure is not limited thereto.

In some implementations, the memory cell region MCRa may include the memory cell array, and the peripheral circuit region PCRa may include the page buffer circuit. For example, the memory cell region MCRa may include a plurality of memory cells which are disposed under the plurality of bit lines BLs and are capable of being connected to the page buffer circuit through the plurality of bit lines BLs. For example, the peripheral circuit region PCRa may include a plurality of page buffer units respectively connected to the plurality of bit lines BLs, and each of the plurality of page buffer units may include a plurality of circuits or a plurality of transistors. As described with reference to FIG. 6, each of the plurality of page buffer units may be connected to one bit line and may include the precharge circuit PRC, the sensing latch SL, the force latch FL, the upper bit latch ML, the lower bit latch LL, the cache latch CL, and the plurality of transistors NM1, NM2, NM3, NM4, NM5, NM6, NM7, and PM. As illustrated in FIG. 7, the peripheral circuit region PCRa may include transistors TR1, TR2, TR3, TR4, etc., and various components included in one page buffer unit may be implemented by using the transistors TR1, TR2, TR3, TR4, etc.

In some implementations, the peripheral circuit region PCRa may include a plurality of metal layers LM0, LM1, and LM2 and may further include a plurality of contacts LC0, LC1, and LC2 for connecting two of the plurality of metal layers LM0, LM1, and LM2 or electrically connecting the metal layer LM0 and the substrate. For example, the metal layer LM1 may be formed over the metal layer LM0, and the metal layer LM2 may be formed over the metal layer LM1. For convenience of description, three metal layers are illustrated in FIG. 7, and the number of metal layers included in the peripheral circuit region PCRa is provided only as an example.

In some implementations, in the metal layers LM0 and LM1, the metal layer LM0 may be referred to as a “lower metal layer”, and the metal layer LM1 may be referred to as an “upper metal layer”. In the above description, the metal layer LM1 among the metal layers LM1 and LM2 may be referred to as a “lower metal layer”, and the metal layer LM2 among the metal layers LM1 and LM2 may be referred to as an “upper metal layer”. In the metal layers LM0 and LM2, the metal layer LM0 may be referred to as a “lower metal layer”, and the metal layer LM2 may be referred to as an “upper metal layer”.

In some implementations, a sensing node which each of the plurality of page buffer units includes may be implemented by using the lower metal layer and the upper metal layer. As described with reference to FIG. 1, the sensing node may include the lower metal layer and the one or more upper metal layers respectively extending in given directions, and the capacitance of the sensing node may have a given value determined by the lower metal layer and may be increased by the one or more upper metal layers.

In some implementations, the lower metal pattern may be formed in the lower metal layer, and the one or more upper metal patterns may be formed in the upper metal layer.

FIGS. 8, 9, 10, 11, and 12 are diagrams illustrating examples of a sensing node included in a page buffer unit of FIG. 1 according to some implementations. In FIGS. 8 to 12, page buffer circuits 500a, 500b, 500c, 500d, and 500e may correspond to the page buffer circuit 500 illustrated in FIG. 5.

For convenience of description, some of the plurality of page buffer units PBU11 to PBU1(n/6), PBU21 to PBU2(n/6), PBU31 to PBU3(n/6), PBU41 to PBU4(n/6), PBU51 to PBU5(n/6), and PBU61 to PBU6(n/6) included in the page buffer circuit 500 are illustrated in FIGS. 8 to 12. An example in which each of the page buffer units 500a to 500e only includes the page buffer units PBU11 to PBU1(n/6) included in the page buffer unit group PBU_G1 is illustrated in FIGS. 8 to 12.

In FIG. 8, the page buffer circuit 500a may include the page buffer units PBU11 to PBU1(n/6) disposed adjacent to each other along the second horizontal direction HD2. Each of the page buffer units PBU11 to PBU1(n/6) may include a sensing node, and the sensing node may include a lower metal pattern which extends in the first horizontal direction HD1 and an upper metal pattern which is spaced from the lower metal pattern in the vertical direction VD, is electrically connected to the lower metal pattern, and extends in the second horizontal direction HD2 or the direction facing away from the second horizontal direction HD2.

For example, the sensing node of the page buffer unit PU11 may include a lower metal pattern MP1-1 and an upper metal pattern MP1-2a. The lower metal pattern MP1-1 and the upper metal pattern MP1-2a may be electrically connected by a contact SC1.

For example, the sensing node of the page buffer unit PU12 may include a lower metal pattern MP2-1 and an upper metal pattern MP2-2a. The lower metal pattern MP2-1 and the upper metal pattern MP2-2a may be electrically connected by a contact SC2.

For example, the sensing node of the page buffer unit PU13 may include a lower metal pattern MP3-1 and an upper metal pattern MP3-2a. The lower metal pattern MP3-1 and the upper metal pattern MP3-2a may be electrically connected by a contact SC3.

For example, the sensing node of the page buffer unit PU1(n/6) may include a lower metal pattern MP(n/6)-1 and an upper metal pattern MP(n/6)-2a. The lower metal pattern MP(n/6)-1 and the upper metal pattern MP(n/6)-2a may be electrically connected by a contact SC(n/6).

In some implementations, the upper metal pattern may extend across (or to overlap) two or more of the page buffer units PBU11 to PBU1(n/6). For example, the upper metal pattern MP1-2a may extend across (or to overlap) the page buffer units PBU11 and PBU12. The upper metal pattern MP2-2a may extend across (or to overlap) the page buffer units PBU12 and PBU13.

In some implementations, the page buffer circuit 500a may include a first page buffer unit and a second page buffer unit. For example, a first sensing node of the first page buffer unit may include a first lower metal pattern and one or more first upper metal patterns. The first lower metal pattern may extend in the first horizontal direction HD1, and the one or more first upper metal patterns may be spaced from the first lower metal pattern in the vertical direction VD and may extend in the second horizontal direction HD2 or the direction facing away from the second horizontal direction HD2.

For example, a second sensing node of the second page buffer unit may include a second lower metal pattern and one or more second upper metal patterns. The second lower metal pattern may extend in the first horizontal direction HD1, and the one or more second upper metal patterns may be spaced from the second lower metal pattern in the vertical direction VD and may extend in the second horizontal direction HD2 or the direction facing away from the second horizontal direction HD2.

For example, the first page buffer unit (e.g., PBU11) may be firstly disposed along the second horizontal direction HD2, and the second page buffer unit (e.g., PBU1(n/6)) may be finally disposed along the second horizontal direction HD2. The one or more first upper metal patterns (e.g., MP1-2a) may extend in the second horizontal direction HD2 from above the first page buffer unit, and the one or more second upper metal patterns (e.g., MP(n/6)-2a) may extend in the direction facing away from the second horizontal direction HD2 from above the second page buffer unit.

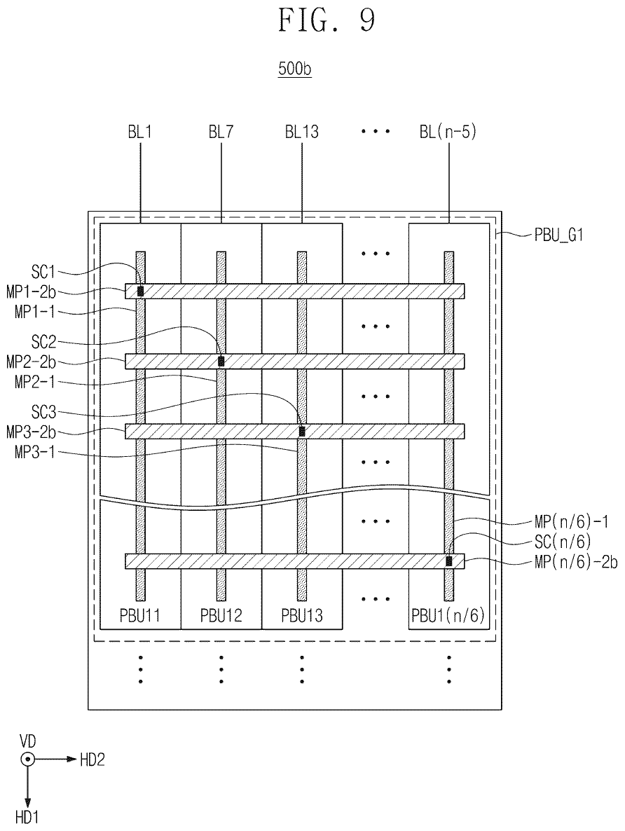

In FIG. 9, the page buffer circuit 500b may include the page buffer units PBU11 to PBU1(n/6) disposed adjacent to each other along the second horizontal direction HD2. Each of the page buffer units PBU11 to PBU1(n/6) may include a sensing node, and the sensing node may include a lower metal pattern which extends in the first horizontal direction HD1 and an upper metal pattern which is spaced from the lower metal pattern in the vertical direction VD, is electrically connected to the lower metal pattern, and extends in the second horizontal direction HD2 or the direction facing away from the second horizontal direction HD2.

For example, the sensing node of the page buffer unit PU11 may include the lower metal pattern MP1-1 and an upper metal pattern MP1-2b. The lower metal pattern MP1-1 and the upper metal pattern MP1-2b may be electrically connected by the contact SC1.

For example, the sensing node of the page buffer unit PU12 may include the lower metal pattern MP2-1 and an upper metal pattern MP2-2b. The lower metal pattern MP2-1 and the upper metal pattern MP2-2b may be electrically connected by the contact SC2.

For example, the sensing node of the page buffer unit PU13 may include the lower metal pattern MP3-1 and an upper metal pattern MP3-2b. The lower metal pattern MP3-1 and the upper metal pattern MP3-2b may be electrically connected by the contact SC3.

For example, the sensing node of the page buffer unit PU1(n/6) may include the lower metal pattern MP(n/6)-1 and an upper metal pattern MP(n/6)-2b. The lower metal pattern MP(n/6)-1 and the upper metal pattern MP(n/6)-2b may be electrically connected by the contact SC(n/6).

In some implementations, the upper metal pattern may extend across (or to overlap) two or more of the page buffer units PBU11 to PBU1(n/6). For example, the upper metal pattern may extend across the whole row where a plurality of page buffer units are disposed. For example, each of the upper metal patterns MP1-2b, MP2-2b, MP3-2b, . . . , MP(n/6)-2b may extend across all the page buffer units PBU11 to PBU1(n/6).

In some implementations, the page buffer circuit 500 may include a third page buffer unit and a fourth page buffer unit. For example, a third sensing node of the third page buffer unit may include a third lower metal pattern and one or more third upper metal patterns. The third lower metal pattern may extend in the first horizontal direction HD1, and the one or more third upper metal patterns may be spaced from the third lower metal pattern in the vertical direction VD and may extend in the second horizontal direction HD2 or the direction facing away from the second horizontal direction HD2.

For example, a fourth sensing node of the fourth page buffer unit may include a fourth lower metal pattern and one or more fourth upper metal patterns. The fourth lower metal pattern may extend in the first horizontal direction HD1, and the one or more fourth upper metal patterns may be spaced from the fourth lower metal pattern in the vertical direction VD and may extend in the second horizontal direction HD2 or the direction facing away from the second horizontal direction HD2.

For example, the third page buffer unit (e.g., PBU11) may be firstly disposed along the second horizontal direction HD2, and the fourth page buffer unit (e.g., PBU1(n/6)) may be finally disposed along the second horizontal direction HD2. The one or more third upper metal patterns (e.g., MP1-2b) may extend in the second horizontal direction HD2 from above the third page buffer unit, and the one or more fourth upper metal patterns (e.g., MP(n/6)-2b) may extend in the direction facing away from the second horizontal direction HD2 from above the fourth page buffer unit.

In some implementations, the page buffer circuit 500b may further include a fifth page buffer unit (e.g., PBU12) disposed between the third page buffer unit and the fourth page buffer unit along the second horizontal direction HD2.

For example, a fifth sensing node of the fifth page buffer unit may include a fifth lower metal pattern (e.g., MP2-1) and one or more fifth upper metal patterns (e.g., MP2-2b). The fifth lower metal pattern may extend in the first horizontal direction HD1, and the one or more fifth upper metal patterns may be spaced from the fifth lower metal pattern in the vertical direction VD and may extend in the second horizontal direction HD2 or the direction facing away from the second horizontal direction HD2.

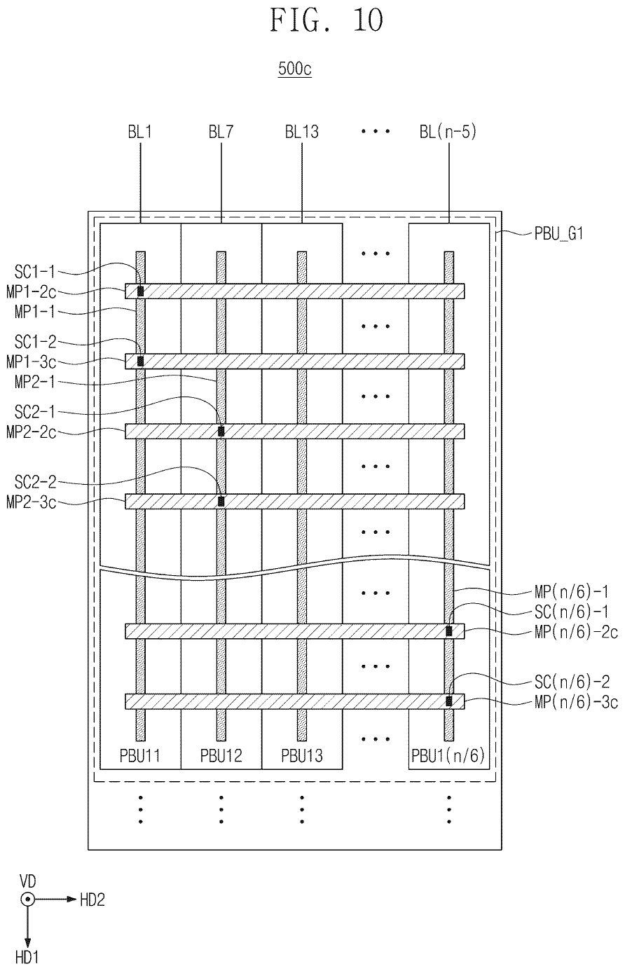

In FIG. 10, the page buffer circuit 500c may include the page buffer units PBU11 to PBU1(n/6) disposed adjacent to each other along the second horizontal direction HD2. Each of the page buffer units PBU11 to PBU1(n/6) may include a sensing node, and the sensing node may include a lower metal pattern which extends in the first horizontal direction HD1 and two or more upper metal patterns which are spaced from the lower metal pattern in the vertical direction VD, is electrically connected to the lower metal pattern, and extend in the second horizontal direction HD2 or the direction facing away from the second horizontal direction HD2.

For example, the sensing node of the page buffer unit PBU11 may include the lower metal pattern MP1-1 and upper metal patterns MP1-2c and MP1-3c. The lower metal pattern MP1-1 and the upper metal pattern MP1-2c may be electrically connected by a contact SC1-1, and the lower metal pattern MP1-1 and the upper metal patterns MP1-3c may be electrically connected by a contacts SC1-2.

For example, the sensing node of the page buffer unit PBU12 may include the lower metal pattern MP2-1 and upper metal patterns MP2-2c and MP2-3c. The lower metal pattern MP2-1 and the upper metal pattern MP2-2c may be electrically connected by a contact SC2-1, and the lower metal pattern MP2-1 and the upper metal patterns MP2-3c may be electrically connected by a contacts SC2-2.

For example, the sensing node of the page buffer unit PBU1(n/6) may include the lower metal pattern MP(n/6)-1 and upper metal patterns MP(n/6)-2c and MP(n/6)-3c. The lower metal pattern MP(n/6)-1 and the upper metal patterns MP(n/6)-2c may be electrically connected by a contact SC(n/6)-1, and the lower metal pattern MP(n/6)-1 and the upper metal patterns MP(n/6)-3c may be electrically connected by a contacts SC(n/6)-2.

In some implementations, the upper metal patterns may extend across (or to overlap) two or more of the page buffer units PBU11 to PBU1(n/6). For example, the upper metal patterns may extend across the whole row where a plurality of page buffer units are disposed. For example, each of the upper metal patterns MP1-2c, MP1-3c, MP2-2c, MP2-3c, . . . , MP(n/6)-2c, MP(n/6)-3c may extend across all the page buffer units PBU11 to PBU1(n/6).

In FIGS. 8, 9, and 10, the number of upper metal patterns may be determined based on a length of a lower metal pattern. For example, the capacitance of the sensing node of the page buffer unit may increase in proportion to a length of a lower metal pattern and lengths of two or more upper metal patterns. For example, the capacitance of the sensing node may have a first value by the lower metal pattern and may increase to have a value greater than the first value by the one or more upper metal patterns.

In some implementations, as the length of the lower metal pattern decreases, the number of one or more upper metal patterns may increase. For example, as the length of the lower metal pattern in the first horizontal direction HD1 decreases, the number of one or more upper metal patterns may increase. In this case, like the sensing nodes included in the page buffer circuit 500c illustrated in FIG. 10, the sensing nodes included in the page buffer circuit 500a or 500b illustrated in FIG. 8 or 9 may be changed and implemented in such a way that the number of upper metal patterns associated with one page buffer unit increases.

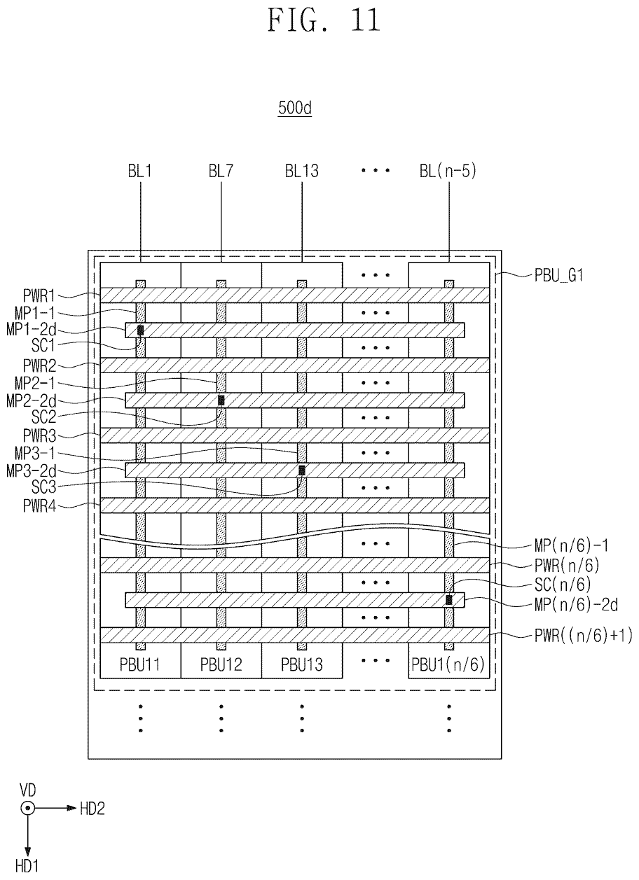

In FIG. 11, compared to the page buffer circuit 500b of FIG. 9, the page buffer circuit 500d may further include one or more power patterns which are disposed over the page buffer units PBU11 to PBU1(n/6) and are formed in an upper metal layer. For example, the page buffer circuit 500d may further include power patterns PWR1, PWR2, PWR3, PWR4, . . . , PWR(n/6), PWR((n/6)+1) which are formed in the same metal layer as upper metal patterns MP1-2d, MP2-2d, MP3-2d, . . . , MP(n/6)-2d.

In some implementations, one or more upper metal patterns and the one or more power patterns may be alternately disposed along the first horizontal direction HD1. The one or more upper metal pattern may include a first upper metal pattern, the one or more power patterns may include a first power pattern, and the first power pattern and the first upper metal pattern may be sequentially disposed along the first horizontal direction HD1. For example, the upper metal patterns MP1-2d, MP2-2d, MP3-2d, . . . , MP(n/6)-2d and the power patterns PWR1, PWR2, PWR3, PWR4, . . . , PWR(n/6), PWR((n/6)+1) may be alternately disposed along the first horizontal direction HD1. For example, the power pattern PWR1, the upper metal pattern MP1-2d, the power pattern PWR2, the upper metal pattern MP2-2d, the power pattern PWR3, the upper metal pattern MP3-2d, . . . , the power pattern PWR(n/6), the upper metal pattern MP(n/6)-2d, and the power pattern PWR(n/6)+1 may be sequentially disposed along the first horizontal direction HD1.

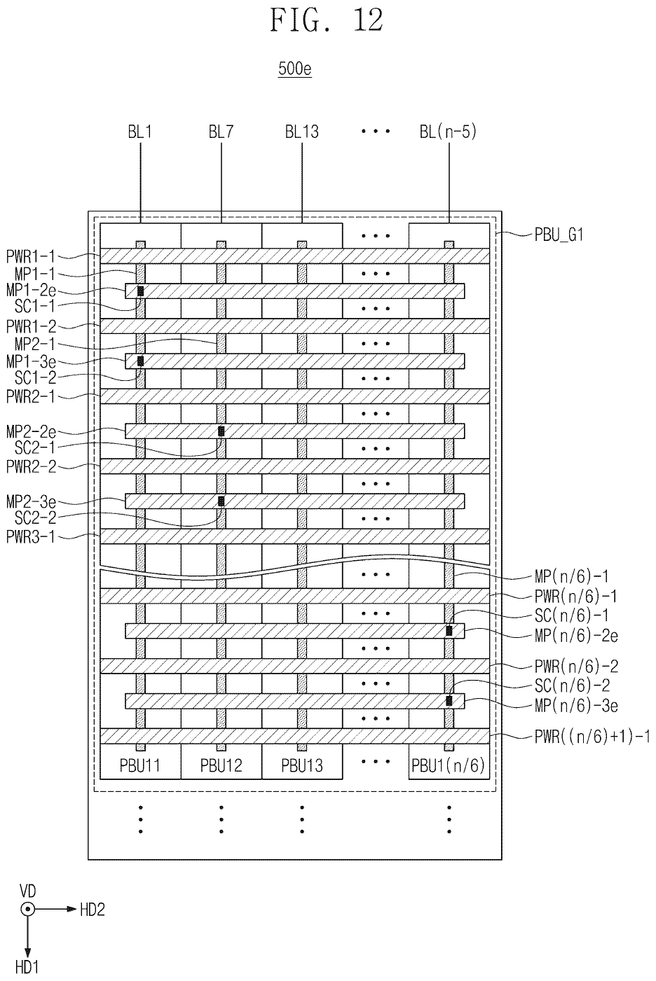

In FIG. 12, compared to the page buffer circuit 500c of FIG. 10, the page buffer circuit 500e may further include one or more power patterns which are disposed over the page buffer units PBU11 to PBU1(n/6) and are formed in an upper metal layer. For example, the page buffer circuit 500e may further include power patterns PWR1-1, PWR1-2, PWR2-1 PWR2-2, PWR3-1, . . . , PWR(n/6)-1, PWR(n/6)-2, PWR((n/6)+1)-1 which are formed in the same metal layer as upper . . . , metal patterns MP1-2e, MP1-3e, MP2-2e, MP2-3e, . . . , MP(n/6)-2e, MP(n/6)-3e.

In some implementations, one or more upper metal patterns and the one or more power patterns may be alternately disposed along the first horizontal direction HD1. The one or more upper metal pattern may include a first upper metal pattern and a second upper metal pattern, the one or more power patterns may include a first power pattern and a second power pattern, and the first power pattern, the first upper metal pattern, the second power pattern, and the second upper metal pattern may be sequentially disposed along the first horizontal direction HD1. The one or more power patterns may further include a third power pattern, and the first power pattern, the first upper metal pattern, the second power pattern, the second upper metal pattern, and the third power pattern may be sequentially disposed along the first horizontal direction HD1. For example, upper metal patterns MP1-2e, MP1-3e, MP2-2e, MP2-3e, . . . , MP(n/6)-2e, MP(n/6)-3e and power patterns PWR1-1, PWR1-2, PWR2-1, PWR2-2, PWR3-1, . . . , PWR(n/6)-1, PWR(n/6)-2, PWR((n/6)+1)-1 may be alternately disposed along the first horizontal direction HD1. For example, the power pattern PWR1-1, the upper metal pattern MP1-2e, the power pattern PWR1-2, the upper metal pattern MP1-3e, the power pattern PWR2-1, the upper metal pattern MP2-2e, the power pattern PWR2-2, the upper metal pattern MP2-3e, the power pattern PWR3-1, . . . , the power pattern PWR(n/6)-1, the upper metal pattern MP(n/6)-2e, the power pattern PWRPWR(n/6)-2, the upper metal pattern MP(n/6)-3e, and the power pattern PWR((n/6)+1)-1 may be sequentially disposed along the first horizontal direction HD1.

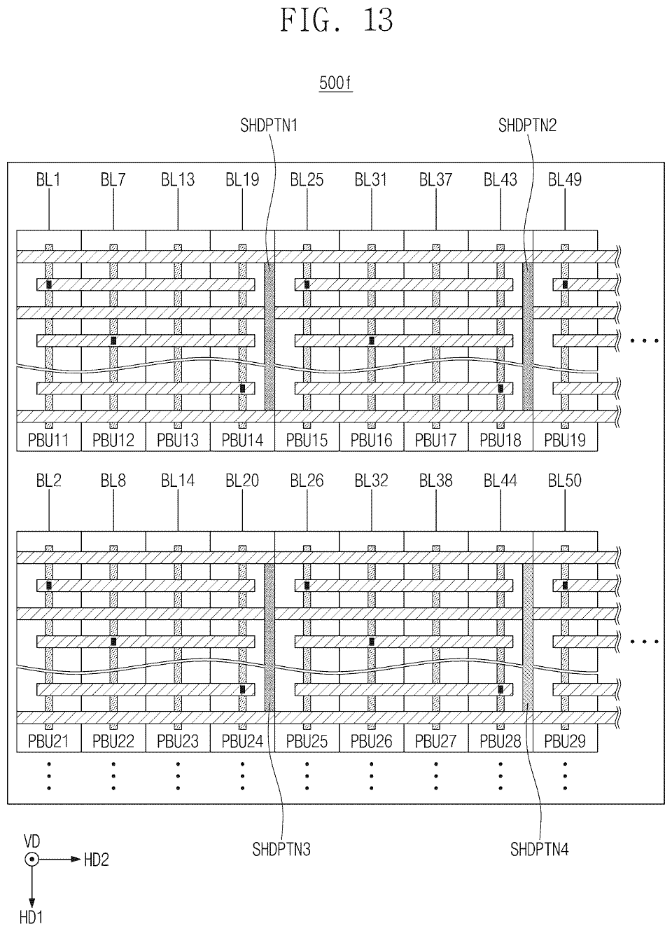

FIG. 13 is a diagram for describing examples of shielding patterns included in the semiconductor memory device of FIG. 1, 2, or 5, and capable of being implemented together with sensing nodes illustrated in FIGS. 8 to 12 according to some implementations. In FIG. 13, a page buffer circuit 500f may correspond to the page buffer circuit 500 illustrated in FIG. 5.

For convenience of description, some of the plurality of page buffer units PBU11 to PBU1(n/6), PBU21 to PBU2(n/6), PBU31 to PBU3(n/6), PBU41 to PBU4(n/6), PBU51 to PBU5(n/6), and PBU61 to PBU6(n/6) included in the page buffer circuit 500 will be illustrated in FIG. 13. For example, the page buffer units PBU11, PBU12, PBU13, PBU14, PBU15, PBU16, PBU17, PBU18, PBU19, PBU21, PBU22, PBU23, PBU24, PBU25, PBU26, PBU27, PBU28, and PBU29 of the page buffer circuit 500f, which are respectively connected to the bit lines BL1, BL2, BL7, BL8, BL13, BL14, BL19, BL20, BL25, BL26, BL31, BL32, BL37, BL38, BL43, BL44, BL49, and BL50 are only illustrated in FIG. 13.

In FIGS. 13, the page buffer circuit 500f may further include a plurality of shielding patterns SHDPTN1, SHDPTN2, SHDPTN3, and SHDPTN4.

In some implementations, the plurality of shielding patterns SHDPTN1, SHDPTN2, SHDPTN3, and SHDPTN4 may be disposed over some of the plurality of page buffer units PBU11 to PBU19 and PBU21 to PBU29. For example, as illustrated in FIG. 13, the shielding pattern SHDPTN1 may be disposed over the page buffer unit PBU14, and the shielding pattern SHDPTN2 may be disposed over the page buffer unit PBU18. The shielding pattern SHDPTN3 may be disposed over the page buffer unit PBU24, and the shielding pattern SHDPTN4 may be disposed over the page buffer unit PBU28. However, the present disclosure is not limited thereto. The number of shielding patterns included in the page buffer circuit 500f or placement locations of shielding patterns are provided as an example. For example, in the page buffer circuit 500f, the shielding patterns may be disposed along the second horizontal direction HD2 at given intervals at one row where page buffer units are disposed.

In some implementations, each of the plurality of shielding patterns SHDPTN1, SHDPTN2, SHDPTN3, and SHDPTN4 may extend in the first horizontal direction HD1 from above a page buffer unit where a relevant shielding pattern is disposed. For example, each of shielding patterns included in the page buffer circuit 500f may be disposed to cover a portion of an upper surface of a page buffer unit where a relevant shielding pattern is disposed. However, the present disclosure is not limited thereto. For example, each of the shielding patterns may be disposed to cover the whole upper surface of the page buffer unit where a relevant shielding pattern is disposed along the first horizontal direction HD1.

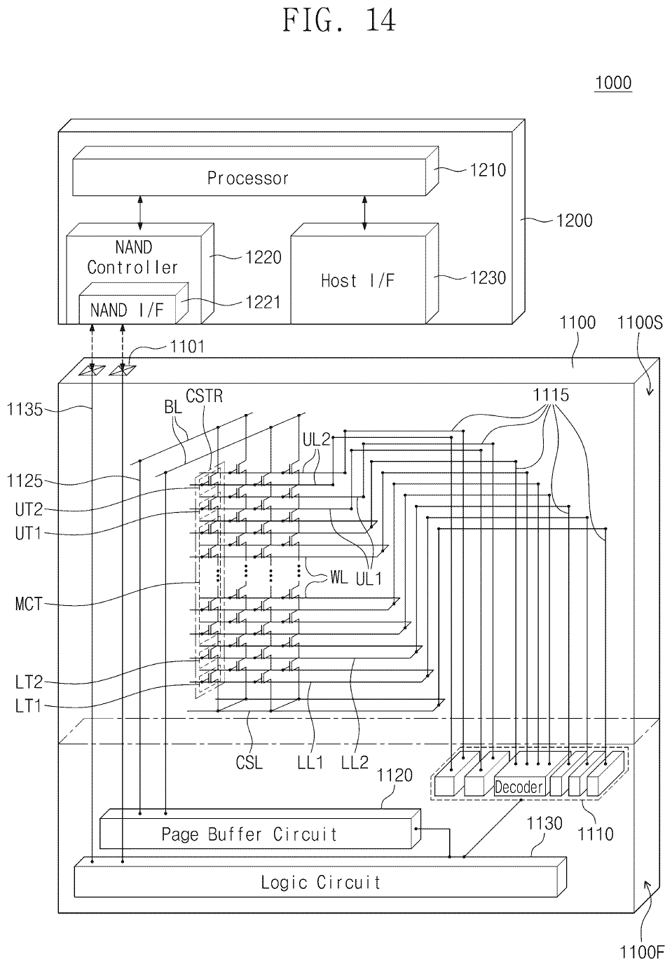

FIG. 14 is a diagram illustrating an example of an electronic system including a semiconductor memory device according to some implementations. In FIG. 14, an electronic system 1000 may include a semiconductor memory device 1100 and a controller 1200 electrically connected to the semiconductor memory device 1100. The electronic system 1000 may be a storage device which includes one or plural semiconductor memory devices 1100 or an electronic device which includes the storage device. For example, the electronic system 1000 may be a device, which includes one or plural semiconductor memory devices 1100, such as a solid state drive (SSD) device, a universal serial bus (USB) device, a computing system, a medical device, or a communication device.

The semiconductor memory device 1100 may be a nonvolatile memory device, for example, a three-dimensional NAND flash memory device. However, the present disclosure is not limited thereto. For example, the semiconductor memory device 1100 may be applied to any other semiconductor memory device including a memory cell array and peripheral circuits.

The semiconductor memory device 1100 may include, for example, a first region 1100F and a second region 1100S on the first region 1100F. As another example, the first region 1100F may be disposed next to the second region 1100S. The first region 1100F may be a peripheral circuit region including a decoder circuit 1110, a page buffer circuit 1120, and a logic circuit 1130. The second region 1100S may be a memory cell region including a bit line BL, a common source line CSL, word lines WL, first lines LL1 and LL2, second lines UL1 and UL2, and memory cell strings CSTR between the bit lines BL and the common source line CSL. For example, the first region 1100F may be the peripheral circuit region PCR of FIG. 1, the peripheral circuit 350 of FIG. 2, or the peripheral circuit region PCRa of FIG. 7. For example, the second region 1100S may be the memory cell region MCR of FIG. 1 or the memory cell region MCRa of FIG. 7. For example, the page buffer circuit 1120 may include the page buffer circuit included in the semiconductor memory device according to embodiments of the present disclosure. Accordingly, the page buffer circuit 1120 may include a plurality of page buffer units each including a sensing node, and the sensing node may be implemented by the metal patterns with given shapes described with reference to FIGS. 8 to 12 and may further include the shielding patterns described with reference to FIG. 13.

In the second region 1100S, each of the memory cell strings CSTR may include first transistors LT1 and LT2 adjacent to the common source line CSL, second transistors UT1 and UT2 adjacent to the bit line BL, and a plurality of memory cell transistors MCT disposed between the first transistors LT1 and LT2 and the second transistors UT1 and UT2. The number of first transistors LT1 and LT2 and the number of second transistors UT1 and UT2 may be variously changed or modified depending on some implementations.

For example, the first transistors LT1 and LT2 may include ground selection transistors, and the second transistors UT1 and UT2 may include string selection transistors. The first lines LL1 and LL2 may be respectively used as gate electrodes of the first transistors LT1 and LT2. The word lines WL may be used as gate electrodes of the memory cell transistors MCT. The second lines UL1 and UL2 may be respectively used as gate electrodes of the second transistors UT1 and UT2.

For example, the first transistors LT1 and LT2 may include the first erase control transistor LT1 and the ground selection transistor LT2 connected in series. The second transistors UT1 and UT2 may include the string selection transistor UT1 and the second line erase control transistor UT2 connected in series. At least one of the first erase control transistor LT1 and the second line erase control transistor UT2 may be used for the erase operation of erasing data stored in the memory cell transistors MCT by using the gate induced drain leakage (GIDL).

The common source line CSL, the first lines LL1 and LL2, the word lines WL, and the second lines UL1 and UL2 may be electrically connected to the decoder circuit 1110 through first connection lines 1115 which extend from the inside of the first region 1100F to the second region 1100S. The bit line BL may be electrically connected to the page buffer circuit 1120 through second connection lines 1125 which extend from the inside of the first region 1100F to the second region 1100S.

In the first region 1100F, the decoder circuit 1110 and the page buffer circuit 1120 may perform a control operation on at least one memory cell transistor selected from the plurality of memory cell transistors MCT. The decoder circuit 1110 and the page buffer circuit 1120 may be controlled by the logic circuit 1130. The semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 which extends from the inside of the first region 1100F to the second region 1100S.

The controller 1200 may include a processor 1210, a NAND controller 1220, and a host interface 1230. For example, the electronic system 1000 may include the plurality of semiconductor memory devices 1100; in this case, the controller 1200 may control the plurality of semiconductor memory devices 1100.

The processor 1210 may control all operations of the electronic system 1000 including the controller 1200. The processor 1210 may operate based on given firmware and may control the NAND controller 1220 to access the semiconductor memory device 1100. The NAND controller 1220 may include a NAND interface 1221 which processes the communication with the semiconductor memory device 1100. A control command for controlling the semiconductor memory device 1100, data to be recorded at the memory cell transistors MCT of the semiconductor memory device 1100, data read from the memory cell transistors MCT of the semiconductor memory device 1100, etc. may be transmitted through the NAND interface 1221. The host interface 1230 may provide a communication function between the electronic system 1000 and an external host. When a control command is received from the external host through the host interface 1230, the processor 1210 may control the semiconductor memory device 1100 in response to the control command.

As described above, a semiconductor memory device may include a page buffer circuit including a plurality of page buffer units, each of the plurality of page buffer units may include a sensing node, and the sensing node may be implemented with metal patterns with given shapes. The metal patterns may include a lower metal layer and one or more upper metal layers respectively extending in given directions, and the capacitance of the sensing node may have a given value determined by the lower metal pattern and may be increased by the one or more upper metal patterns. The sensing node may be implemented by the above metal patterns to have a capacitance of a sufficient value and may satisfy the hardware specifications associated with read or write performance of a semiconductor memory device even in an external environment including a noise or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
a memory cell array formed in a memory cell region; and
a page buffer circuit formed in a peripheral circuit region and including a plurality of page buffer units, each buffer unit including a sensing node for reading data stored in the memory cell array,
wherein the sensing node includes:
a lower metal pattern extending in a first horizontal direction; and
one or more upper metal patterns spaced from the lower metal pattern in a vertical direction, electrically connected to the lower metal pattern, and extending in a second horizontal direction perpendicular to the first horizontal direction.

2. The semiconductor memory device of claim 1,
wherein the plurality of page buffer units are disposed adjacent to each other along the second horizontal direction, and
wherein each of the one or more upper metal patterns overlaps two or more of the plurality of page buffer units.

3. The semiconductor memory device of claim 2, wherein a number of the one or more upper metal patterns increases as a length of the lower metal pattern decreases.

4. The semiconductor memory device of claim 2,
wherein the peripheral circuit region includes:
a lower metal layer; and
an upper metal layer disposed over the lower metal layer, and
wherein the lower metal pattern is formed in the lower metal layer, and the one or more upper metal patterns are formed in the upper metal layer.

5. The semiconductor memory device of claim 4, further comprising:
one or more power patterns disposed over the plurality of page buffer units and formed in the upper metal layer.

6. The semiconductor memory device of claim 5, wherein the one or more upper metal patterns and the one or more power patterns are alternately disposed along the first horizontal direction.

7. The semiconductor memory device of claim 5,
wherein the one or more upper metal patterns include a first upper metal pattern,
wherein the one or more power patterns include a first power pattern, and
wherein the first power pattern and the first upper metal pattern are sequentially disposed along the first horizontal direction.

8. The semiconductor memory device of claim 7,
wherein the one or more upper metal patterns further include a second upper metal pattern,
wherein the one or more power patterns further include a second power pattern, and
wherein the first power pattern, the first upper metal pattern, the second power pattern, and the second upper metal pattern are sequentially disposed along the first horizontal direction.

9. The semiconductor memory device of claim 8,
wherein the one or more power patterns further include a third power pattern, and
wherein the first power pattern, the first upper metal pattern, the second power pattern, the second upper metal pattern, and the third power pattern are sequentially disposed along the first horizontal direction.

10. The semiconductor memory device of claim 5, further comprising:
a shielding pattern extending in the first horizontal direction and disposed over a portion of the plurality of page buffer units.

11. The semiconductor memory device of claim 1, wherein the sensing node further includes:
one or more contacts for electrically connecting the lower metal pattern and the one or more upper metal patterns.

12. The semiconductor memory device of claim 1,
wherein the plurality of page buffer units are connected to the memory cell array through bit lines, and
wherein the first horizontal direction is a bit line extension direction in which the bit lines horizontally extend in the memory cell region.

13. The semiconductor memory device of claim 1, wherein the sensing node forms a metal-insulator-metal (MIM) capacitor with one or more metal patterns adjacent thereto.

14. The semiconductor memory device of claim 12, wherein a capacitance of the sensing node is configured to have a first value based on the lower metal pattern, and
wherein the capacitance of the sensing node is configured to, based on the one or more upper metal patterns, increase to a value greater than the first value.

15. A semiconductor memory device comprising:
a memory cell array formed in a memory cell region; and
a page buffer circuit formed in a peripheral circuit region and including a plurality of page buffer units including a first page buffer unit and a second page buffer unit,
wherein a first sensing node of the first page buffer unit includes:
a first lower metal pattern extending in a first horizontal direction; and
one or more first upper metal patterns spaced from the first lower metal pattern in a vertical direction and extending in a second horizontal direction perpendicular to the first horizontal direction, and
wherein a second sensing node of the second page buffer unit includes:
a second lower metal pattern extending in the first horizontal direction; and
one or more second upper metal patterns spaced from the second lower metal pattern in the vertical direction and extending in the second horizontal direction.

16. The semiconductor memory device of claim 15,
wherein the first page buffer unit is disposed along the second horizontal direction, and the second page buffer unit is disposed along the second horizontal direction,
wherein the one or more first upper metal patterns extend in the second horizontal direction above the first page buffer unit, and
wherein the one or more second upper metal patterns extend above the second page buffer unit.

17. The semiconductor memory device of claim 16, wherein the plurality of page buffer units further include:
a third page buffer unit disposed between the first page buffer unit and the second page buffer unit along the second horizontal direction,
wherein a third sensing node of the third page buffer unit includes:
a third lower metal pattern extending in the first horizontal direction; and
one or more third upper metal patterns spaced from the third lower metal pattern in the vertical direction and extending in the second horizontal direction, and
wherein the one or more third upper metal patterns extend in the second horizontal direction above the third page buffer unit.

18. The semiconductor memory device of claim 15, further comprising:
a shielding pattern extending in the first horizontal direction and disposed over the second page buffer unit.

19. The semiconductor memory device of claim 15,
wherein the first page buffer unit and the second page buffer unit are disposed adjacent to each other along the second horizontal direction, and
wherein the one or more first upper metal patterns and the one or more second upper metal pattern are sequentially disposed along the first horizontal direction.

20. A semiconductor memory device with a cell over periphery (COP), comprising:
a memory cell array formed in a memory cell region; and
a page buffer circuit formed in a peripheral circuit region disposed under the memory cell region and including a plurality of page buffer units, each buffer unit including a sensing node for reading data stored in the memory cell array,
wherein the sensing node includes:
a lower metal pattern extending in a first horizontal direction; and
one or more upper metal patterns spaced from the lower metal pattern in a vertical direction, electrically connected to the lower metal pattern, and extending in a second horizontal direction perpendicular to the first horizontal direction,
wherein the peripheral circuit region includes:
a lower metal layer; and
an upper metal layer disposed over the lower metal layer, and
wherein the lower metal pattern is formed in the lower metal layer, and the one or more upper metal patterns are formed in the upper metal layer.
